(19) United States
(12) Patent Application Publication
(10) Pub. No.: US 2024/0404912 A1
(43) Pub. Date: Dec. 5, 2024

(54) SEMICONDUCTOR DEVICE AND SEMICONDUCTOR DEVICE MANUFACTURING METHOD

(71) Applicant: FUJI ELECTRIC CO., LTD., Kawasaki-shi (JP)

(72) Inventors: Taichi ITOH, Matsumoto-city (JP); Yoshihiro KODAIRA, Matsumoto-city (JP)

(73) Assignee: FUJI ELECTRIC CO., LTD., Kawasaki-shi (JP)

(21) Appl. No.: 18/783,205

(22) Filed: Jul. 24, 2024

Related U.S. Application Data
(63) Continuation of application No. PCT/JP2023/021824, filed on Jun. 13, 2023.

(30) Foreign Application Priority Data
Jul. 13, 2022 (JP) 2022-112672

(51) Int. Cl. H01L 23/373; H01L 21/48

(52) U.S. Cl. CPC H01L 23/3731; H01L 21/4807

(57) ABSTRACT

A semiconductor device includes a base plate that includes a body plate containing a silicon carbide, a metal-filled body having a top surface and a bottom surface opposite to each other and having a through hole, and a protective member disposed on the bottom surface of the metal-filled body and having a hardness less than a hardness of the body plate, an insulating board disposed on the base plate, a semiconductor element mounted on a top surface of the base plate via the insulating board, and a cooling member attached to a bottom surface of the base plate and fastened to the base plate with a screw that passes through the through-hole.

### CROSS-REFERENCE TO RELATED APPLICATION

This application is a continuation application of International Application PCT/JP2023/021824 filed on Jun. 13, 2023, which designated the U.S., which claims priority to Japanese Patent Application No. 2022-112672, filed on Jul. 13, 2022, the entire contents of which are incorporated herein by reference.

### BACKGROUND OF THE INVENTION

### 1. Field of the Invention

The embodiment discussed herein relates to a semiconductor device and a semiconductor device manufacturing method.

### 2. Background of the Related Art

In recent years, a silicon carbide formed body (body plate) made of silicon carbide (SiC) and a metal composite has been used as a heat dissipation base plate of a power semiconductor module. The silicon carbide formed body is manufactured by impregnating a molded body obtained by firing silicon carbide with a metal composite.

A cooling member is attached to the heat dissipation base plate of the power semiconductor module with screws or the like. In this case, through-holes for fastening the cooling member to the heat dissipation base plate with the screws are formed in the heat dissipation base plate.

When the through-holes are formed in the silicon carbide formed body of the heat dissipation base plate, because the silicon carbide formed body has a high hardness, it is difficult to conduct cutting processing such as punching, which is normally used for forming a hole in a metal base. Thus, special processing such as waterjet processing is needed. However, because special processing such as waterjet processing is costly, a heat dissipation base plate that uses a single metal material for regions where the through-holes are formed is used.

As a related technique, for example, there has been proposed a heat dissipation component in which the outer periphery of through-holes is a metal portion made of aluminum or an aluminum alloy, and the other portion is made of an aluminum-silicon carbide composite portion (Japanese Laid-open Patent Publication No. 2003-204022). There has also been proposed a heat spreader that is constituted by coating layers and a frame and that has grooves along an outer edge of an inner base material on either a front surface or back surface (International Publication Pamphlet No. WO 2009/098865). Further, there has been proposed a semiconductor module that has a heatsink attached to a base plate, which is a heat dissipation cooling member made of MgSiC, via thermal paste and a metal ring (Japanese Laid-open Patent Publication No. 2018-181893). Furthermore, there has been proposed a bonding board including a metal base plate having a thinned portion. This thinned portion is formed at an opening portion of a through-hole in the metal base plate, and a metal reinforced film is formed on the thinned portion (Japanese Laid-open Patent Publication No. 2016-187009).

As described above, the use of a single metal material in the regions where the through-holes are formed offers the advantage of easier cutting processing. However, a level difference could be generated between the silicon carbide formed body and the metal material of the heat dissipation base plate due to the difference in linear expansion coefficient between the silicon carbide formed body and the metal material. In this state in which the level difference is present, if the cooling member is fastened to the heat dissipation base plate with screws via the through-holes, unnecessary stress is applied to various members of the power semiconductor module by the principle of leverage.

### SUMMARY OF THE INVENTION

According to an aspect, there is provided a semiconductor device, including: a base plate that includes a body plate containing silicon carbide, a metal-filled body having a top surface and a bottom surface opposite to each other, and having a through hole, and a protective member disposed on at least the bottom surface of the metal-filled body and having a hardness less than a hardness of the body plate; an insulating board disposed on the base plate; a semiconductor element mounted on a top surface of the base plate via the insulating board; and a cooling member that is attached to a bottom surface of the base plate and is fastened to the base plate with a screw that passes through the through-hole.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a diagram illustrating an example of a construction of a semiconductor device according to an embodiment;

FIG. 2 is a diagram illustrating a state in which a silicon carbide formed body and metal-filled bodies are planarized. (a) of FIG. 2 is a plan view of a heat dissipation base plate in a manufacturing process, and (b) of FIG. 2 is a side view of the heat dissipation base plate in the manufacturing process as viewed from a direction A;

FIG. 3 is a diagram illustrating a state in which level differences are generated between a silicon carbide formed body and metal-filled bodies. (a) of FIG. 3 is a plan view of a heat dissipation base plate in a manufacturing process, and (b) of FIG. 3 is a side view of the heat dissipation base plate in the manufacturing process as viewed from the direction A;

FIG. 4 is a diagram illustrating generation of stress;

FIG. 5 is a diagram illustrating a base plate manufacturing process;

FIG. 6 is a diagram illustrating a base plate manufacturing process. (a) of FIG. 6 is a plan view of the base plate in a manufacturing process, and (b) of FIG. 6 is a side view illustrating the base plate in the manufacturing process as viewed from the direction A;

FIG. 7 is a diagram illustrating a base plate manufacturing process. (a) of FIG. 7 is a plan view of the base plate in a manufacturing process, and (b) of FIG. 7 is a side view illustrating the base plate in the manufacturing process as viewed from the direction A;

FIG. 8 illustrates a base plate manufacturing process. (a) of FIG. 8 is a plan view of the base plate in a manufacturing process, and (b) of FIG. 8 is a side view illustrating the base plate in the manufacturing process as viewed from the direction A;

FIG. 9 is a diagram illustrating the thicknesses of level differences;

FIG. 10 is a diagram illustrating reduction of generation of stress; and

FIG. 11 is a diagram illustrating a modification of the construction of the semiconductor device according to the present embodiment.

### DETAILED DESCRIPTION OF THE INVENTION

Hereinafter, an embodiment will be described with reference to the accompanying drawings. In the present description and drawings, elements having substantially the same function will be denoted by the same reference character, and redundant description of these elements will be omitted, as needed. In addition, in the following description, “top surface” represents a surface facing upward on paper. Likewise, “up” and “upper portion” represent the upper direction on paper. In addition, “bottom surface” represents a surface facing downward on paper. Likewise, “lower side” represents the lower direction on paper. In all the drawings, the above terms mean their respective directions. Expressions “top surface”, “up”, “upper portion”, “bottom surface”, and “lower side” are simply used as convenient expressions to determine relative positional relationships and do not limit the technical ideas of the embodiment.

### <Construction of Semiconductor Device>

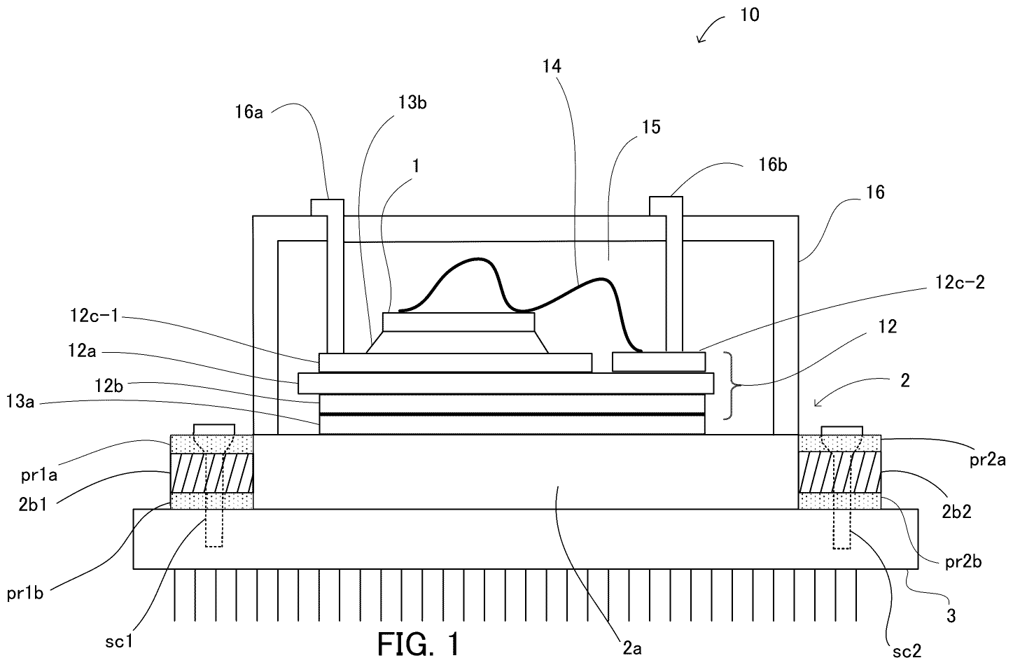

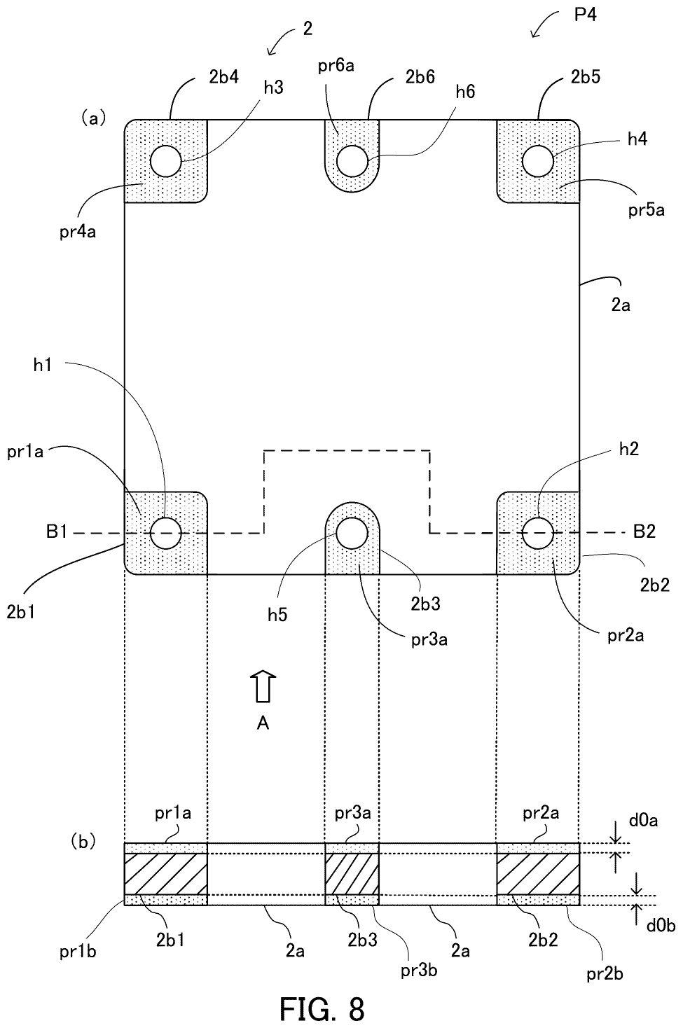

FIG. 1 is a diagram illustrating an example of a construction of a semiconductor device according to an embodiment. A cross-sectional view of a semiconductor device 10 is illustrated. A dashed line B1-B2 illustrated in FIG. 8, which will be described below, is the section line of the cross-sectional view of the semiconductor device 10 illustrated in FIG. 1. The semiconductor device 10 includes an insulating board 12 mounted on a cooling member 3 via a base plate 2, and also includes a semiconductor element 1.

The insulating board 12 includes an insulating plate 12a and patterns (foils) 12b, 12c-1, and 12c-2 (hereinafter, the patterns 12c-1 and 12c-2 will be collectively referred to as patterns 12c, as needed). When the patterns 12b and 12c are, for example, copper patterns, a direct copper bonding (DCB) board in which the patterns 12b and 12c are directly bonded to the insulating plate 12a may be used.

The insulating plate 12a is made of, for example, an insulating material such as a ceramic material such as alumina (Al₂O₃), aluminum nitride (AlN), or silicon nitride (Si₃N₄), a resin material such as epoxy, or an epoxy-resin material using a ceramic material as a filler.

One surface of the base plate 2 is mounted on the top surface of the cooling member 3, and the insulating board 12 is mounted on the other surface of the base plate 2. The pattern 12b of the insulating board 12 is bonded to the base plate 2 via a bonding material 13a (solder or the like). A thermal compound (not illustrated) is formed between the base plate 2 and the top surface of the cooling member 3.

The semiconductor element 1 made of silicon is bonded to the pattern 12c-1 of the insulating board 12 via a bonding material 13b (solder or the like), for example. A wire 14 is, for example, an aluminum wire having a wire diameter of 300 μm to 400 μm.

The wire 14 bonds an electrode of the semiconductor element 1 and the pattern 12c-2 serving as a lead electrode of the insulating board 12. The semiconductor element 1 is provided with, for example, an electrode (Al—Si electrode) coated with an Al—Si alloy film. As the bonding by the wire 14, ultrasonic- and load-based wire bonding is performed. An external terminal 16a formed on a case 16 is bonded to the pattern 12c-1, and an external terminal 16b formed on the case 16 is bonded to the pattern 12c-2.

The insulating board 12 to which the semiconductor element 1 is bonded is stored in the case 16, and a region enclosed by the case 16 and the base plate 2 is sealed by injecting a sealing resin 15. The patterns 12b and 12c of the insulating board 12 are made of a material having an excellent electrical conductivity. This material is, for example, copper, aluminum, or an alloy containing at least one of these kinds of elements. The thickness of each of the patterns 12b and 12c is preferably between 0.10 mm and 2.00 mm, inclusive, more preferably, between 0.20 mm and 1.00 mm, inclusive.

In addition to the semiconductor element 1, a wiring member, such as a bonding wire, a lead frame, or a connection terminal, and an electronic component may be suitably disposed on the patterns 12c, as needed. The patterns 12c may be plated with a material having excellent corrosion resistance. Examples of the material include aluminum, nickel, titanium, chromium, molybdenum, tantalum, niobium, tungsten, vanadium, bismuth, zirconium, hafnium, gold, silver, platinum, palladium, and an alloy containing at least one of these kinds of elements. The number and the arrangement of the patterns 12c and the shapes of the patterns 12c may be suitably selected, depending on the design.

The base plate 2 is a heat dissipation base plate and includes a silicon carbide formed body (body plate containing a silicon carbide) 2a, metal-filled bodies 2b1 and 2b2, and metal-filled bodies 2b3 to 2b6 (not illustrated), and the pattern 12b of the insulating board 12 is bonded to the top surface of the silicon carbide formed body 2a via the bonding material 13a. The silicon carbide formed body 2a is thicker than the metal-filled bodies 2b1 and 2b2.

Protective members pr1a, pr1b, pr2a, and pr2b are formed on surfaces of the metal-filled bodies 2b1 and 2b2. That is, the protective members pr1a and pr2a are formed on surfaces (first surfaces) of the metal-filled bodies 2b1 and 2b2, these surfaces being located near the top surface of the silicon carbide formed body 2a, such that the top surface of the silicon carbide formed body 2a and the top surfaces of the protective members pr1a and pr2a are planarized.

Further, the protective members pr1b and pr2b are formed on surfaces (second surfaces) of the metal-filled bodies 2b1 and 2b2, these surfaces being located near the bottom surface of the silicon carbide formed body 2a, such that the bottom surface of the silicon carbide formed body 2a and the bottom surfaces of the protective members pr1b and pr2b are planarized. The cooling member 3 is fastened to the bottom surface of the base plate 2 with screws sc1 and sc2 passing through through-holes formed in the metal-filled bodies 2b1 and 2b2.

The silicon carbide formed body 2a of the base plate 2 is made of silicon carbide and a metal composite. The metal composite includes a metal having an excellent thermal conductivity. Examples of the metal include aluminum, magnesium, and an alloy containing at least one of these kinds of elements. The silicon carbide formed body 2a may be made of aluminum-silicon nitride (AlSiC), magnesium-silicon nitride (MgSiC), or the like.

The material of the metal-filled bodies 2b1 and 2b2 is, for example, Mg, Al, or an alloy containing at least one of these kinds of elements. The protective members pr1a, pr1b, pr2a, and pr2b are metal plates or elastic materials, and each have a hardness less than that of the silicon carbide formed body 2a. The material of the metal plate is any one of Cu, Al, and Fe, and the elastic material is, for example, a tape. It is desirable that the thermal conductivity of the tape be equal to or greater than of the thermal compound formed between the base plate 2 and the top surface of the cooling member 3. In addition, it is desirable that the tape be a tape in which an adhesive is attached to a metal foil such as a copper foil or an aluminum foil, or a tape in which an adhesive is attached to a resin such as polyimide. The hardness is, for example, Vickers hardness.

The sum of the thickness of the protective member pr1a (first protective member) and the thickness of the protective member pr1b (second protective member) is 1.2% to 2% of the thickness of the silicon carbide formed body 2a. Similarly, the sum of the thickness of the protective member pr2a (first protective member) and the thickness of the protective member pr2b (second protective member) is 1.2% to 2% of the thickness of the silicon carbide formed body 2a. An area of each of the protective members pr1a, pr1b, pr2a, and pr2b is equal to an area covering the top surface or the bottom surface of the metal-filled body 2b1 or 2b2.

The protective member pr1b has an elastic modulus that planarizes the bottom surface of the silicon carbide formed body 2a and the bottom surface of the protective member pr1b when the base plate 2 and the cooling member 3 are fastened to each other with the screw sc1. Similarly, the protective member pr2b has an elastic modulus that planarizes the bottom surface of the silicon carbide formed body 2a and the bottom surface of the protective member pr2b when the base plate 2 and the cooling member 3 are fastened to each other with the screw sc2.

In addition, for example, the surface of the base plate 2 may be plated with a material such as nickel, to improve its corrosion resistance. Specifically, other than nickel, the surface of the base plate 2 may be plated with a nickel-phosphorus alloy or a nickel-boron alloy, for example. The thickness of the plating film is preferably 1 μm or greater, more preferably, 5 μm or greater. The cooling member 3 is a heatsink including at least one fin or is a water-cooled cooling device, for example.

The semiconductor element 1 is a power device made of silicon, silicon carbide, or gallium nitride. The semiconductor element 1 includes a switching element. The switching element is a power metal-oxide-semiconductor field-effect transistor (MOSFET) or an insulated gate bipolar transistor (IGBT), for example.

This semiconductor element 1 has, for example, a drain electrode (a positive electrode or has a collector electrode if the semiconductor element 1 is an IGBT) as a main electrode, a gate electrode as a control electrode, and a source electrode (a negative electrode or has an emitter electrode if the semiconductor element 1 is an IGBT).

The semiconductor element 1 also includes a diode element. The diode element is, for example, a freewheeling diode (FWD) such a Schottky barrier diode (SBD) or a P-intrinsic-N (PiN) diode.

The thickness of the semiconductor element 1 is, for example, between 80 μm and 500 μm, inclusive. The average thickness is about 200 μm. Depending on the need, another electronic component may be disposed on a pattern 12c. Examples of the electronic component include a capacitor, a resistor, a thermistor, a current sensor, and a control integrated circuit (IC).

The case 16 is made of resin. This resin contains a thermoplastic resin as its main component. The thermoplastic resin is, for example, polyphenylene sulfide resin, polybutylene terephthalate resin, polybutylene succinate resin, polyamide resin, or acrylonitrile butadiene styrene resin. For example, silicone gel is used as the sealing resin 15.

### <Stress Generated Due to Level Difference>

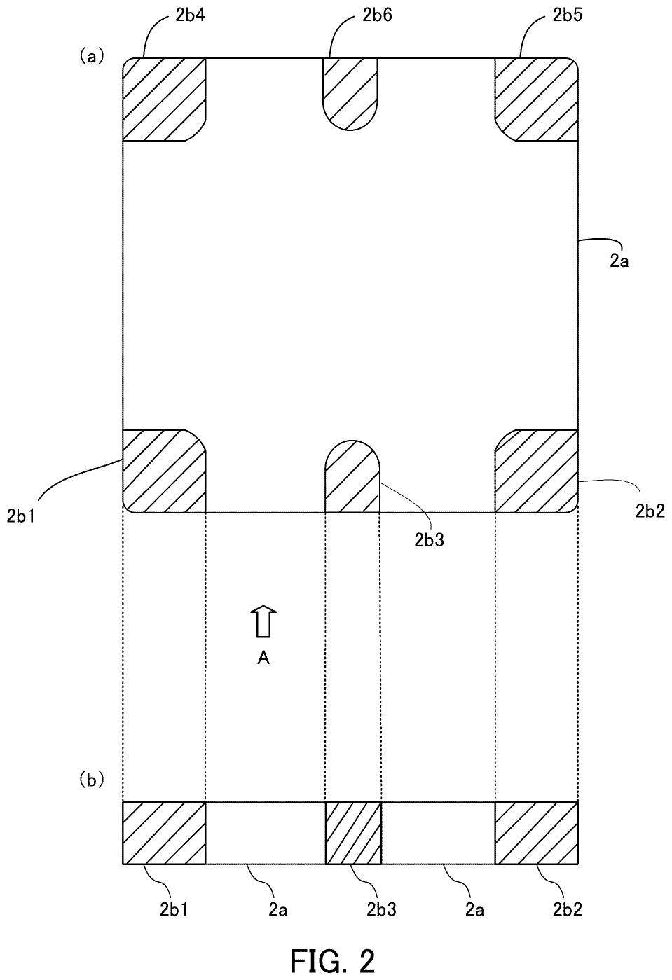

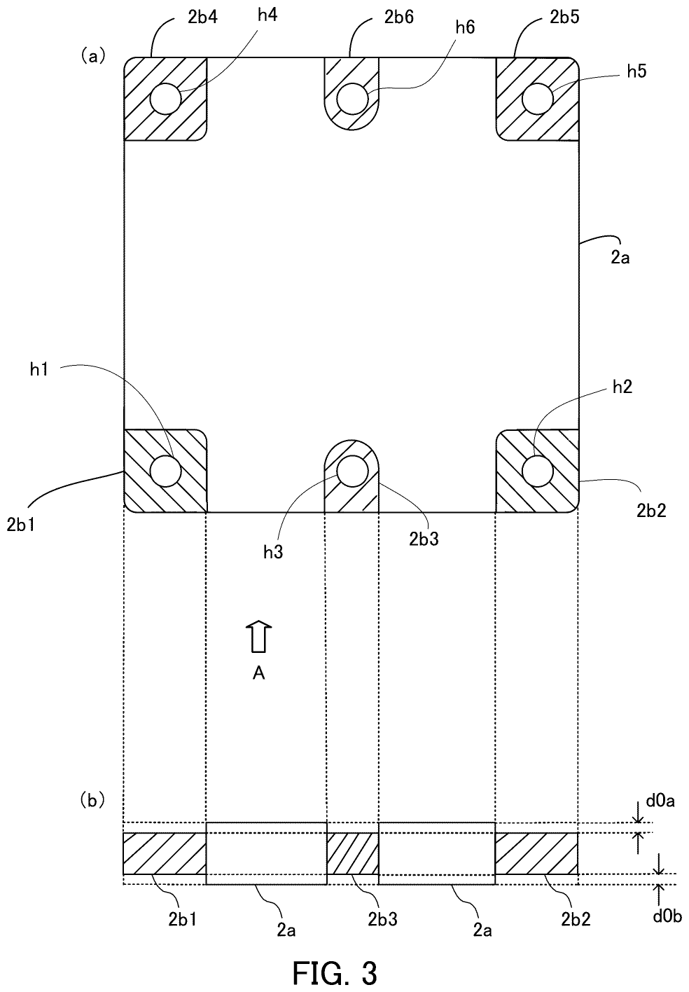

Next, before the present embodiment is described in detail, stress generated due to the level differences between the silicon carbide formed body and metal-filled bodies will be described with reference to FIGS. 2 to 4. FIGS. 2 and 3 are diagrams illustrating a state in which level differences are generated between the silicon carbide formed body and the metal-filled bodies. In each of FIGS. 2 and 3, (a) is a plan view of a heat dissipation base plate in a manufacturing process, and (b) is a side view of the heat dissipation base plate in the manufacturing process as viewed from a direction A.

FIG. 2 illustrates a state in which the metal of the metal-filled bodies 2b1 to 2b6, which are formed by injecting the molten liquid of a metal composite into predetermined regions of the silicon carbide formed body 2a, is melted. At this point, there are no level differences between surfaces of the silicon carbide formed body 2a and surfaces of the metal-filled bodies 2b1 to 2b6. The surfaces of the silicon carbide formed body 2a and the surfaces of the metal-filled bodies 2b1 to 2b6 are planarized.

FIG. 3 illustrates a state in which the molten liquid of the metal composite injected into the predetermined regions of the silicon carbide formed body 2a is solidified, and through-holes h1 to h6 are formed in the metal-filled bodies 2b1 to 2b6, respectively, after the metal is solidified. When the metal is solidified, a level difference d0a is generated between the top surface of the silicon carbide formed body 2a and each of the top surfaces of the metal-filled bodies 2b1 to 2b6 due to the difference in linear expansion coefficient between the silicon carbide formed body 2a and the metal-filled bodies 2b1 to 2b6. In addition, a level difference d0b is generated between the bottom surface of the silicon carbide formed body 2a and each of the bottom surfaces of the metal-filled bodies 2b1 to 2b6.

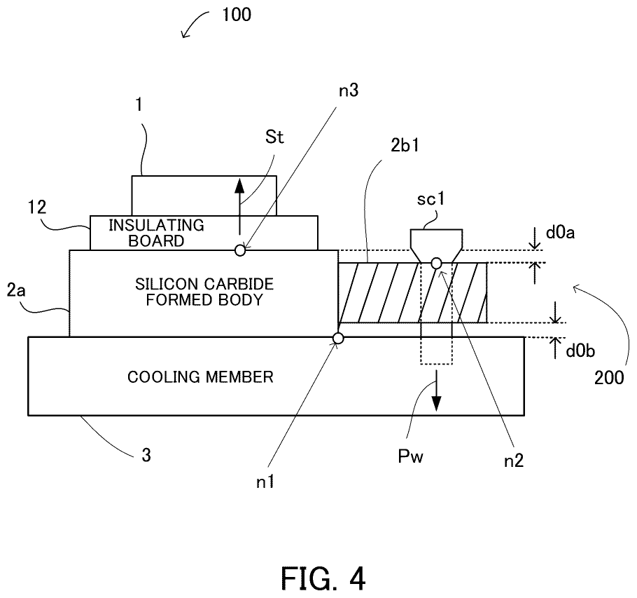

FIG. 4 is a diagram illustrating generation of stress. A conventional power semiconductor module 100 includes a heat dissipation base plate 200, an insulating board 12, a semiconductor element 1, and a cooling member 3. The heat dissipation base plate 200 includes a silicon carbide formed body 2a and a metal-filled body 2b1. The semiconductor element 1 is mounted on the top surface of the silicon carbide formed body 2a via the insulating board 12.

The cooling member 3 is attached to the bottom surface of the heat dissipation base plate 200. In this case, the cooling member 3 is fastened to the heat dissipation base plate 200 with a screw sc1 that passes through a through-hole formed in the metal-filled body 2bl.

As described above, the level differences d0a and d0b are generated between the silicon carbide formed body 2a and the metal-filled body 2b1. Therefore, when the heat dissipation base plate 200 and the cooling member 3 are fastened to each other with the screw sc1, unnecessary stress is generated by the principle of leverage.

That is, a boundary portion n1 between the silicon carbide formed body 2a and the metal-filled body 2b1 having the level difference d0b serves as a fulcrum, a portion n2 to which an axial force Pw of the screw sc1 is applied serves as a point of effort, and a portion n3 on which the semiconductor element 1 is mounted serves as a point of load. Accordingly, unnecessary stress is applied to various members of the power semiconductor module 100.

If such stress is applied, for example, the metal-filled body 2b1 could be distorted, and torque loss of the screw sc1 could be caused. In addition, a stress St concentrated on the point of load could damage or deteriorate the insulating board 12 or the semiconductor device 1.

### <Base Plate Manufacturing Process>

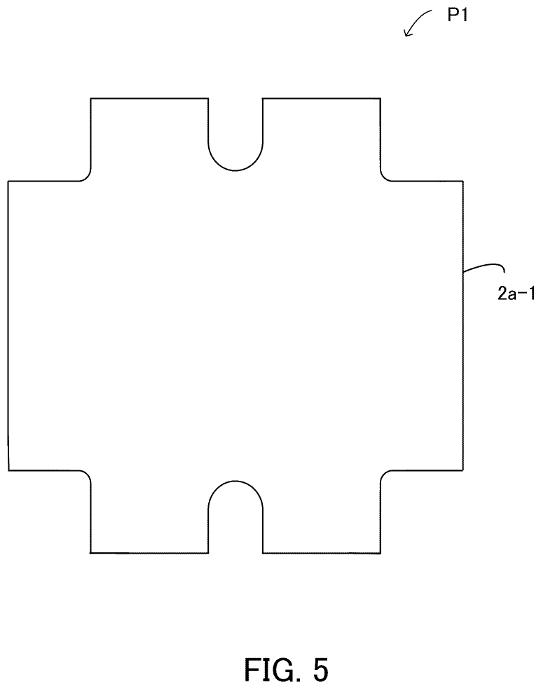

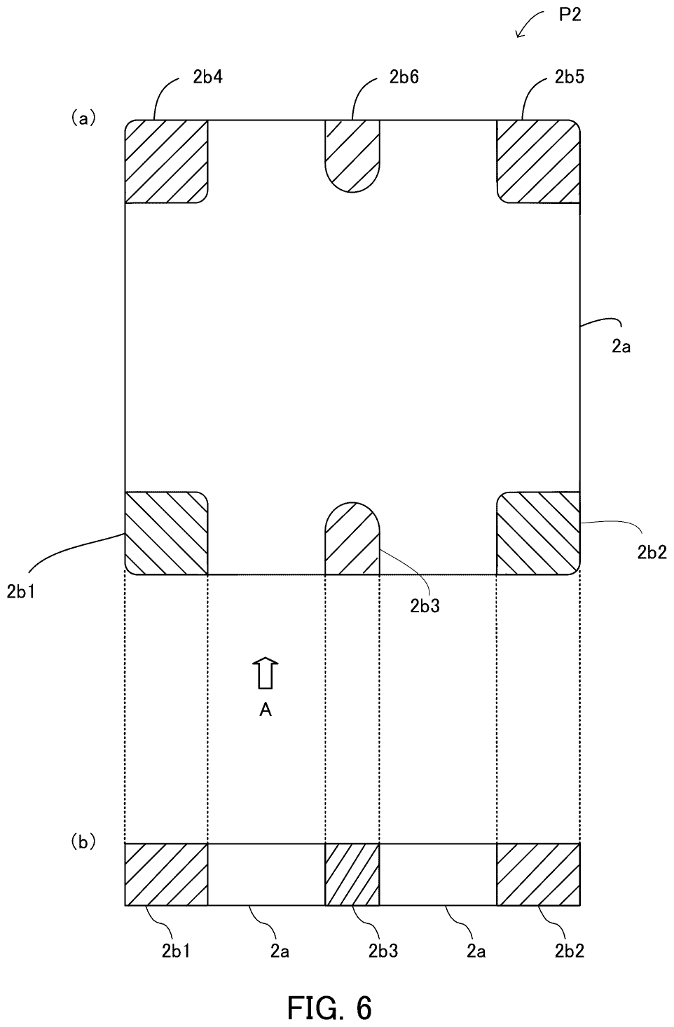

FIGS. 5 to 8 illustrate a base plate manufacturing process. In each of FIGS. 6 to 8, (a) is a plan view of a base plate in a manufacturing process, and (b) illustrates the base plate in the manufacturing process as viewed from a direction A. The dotted line B1-B2 illustrated in FIG. 8 is the section line of the cross-sectional view of the semiconductor device 1 illustrated in FIG. 1.

[Process P1] As illustrated in FIG. 5, a silicon carbide 2a-1 is fired at an area where the peripheral regions of the through-holes are not located.

[Process P2] As illustrated in FIG. 6, the metal-filled bodies 2b1 to 2b6 are formed by injecting the molten liquid of a metal composite into the fired silicon carbide 2a-1 and predetermined regions.

For example, the metal-filled bodies 2b1 to 2b6 are formed at peripheral frame portions (corresponding to the metal-filled bodies 2b3 and 2b6 in the example in FIG. 6) or at corner portions (corresponding to the metal-filled bodies 2b1, 2b2, 2b4, and 2b5 in the example in FIG. 6) of the base plate 2 to be manufactured. The predetermined regions refer to, for example, peripheral regions of the through-holes h1 to h6 to be formed in the base plate 2.

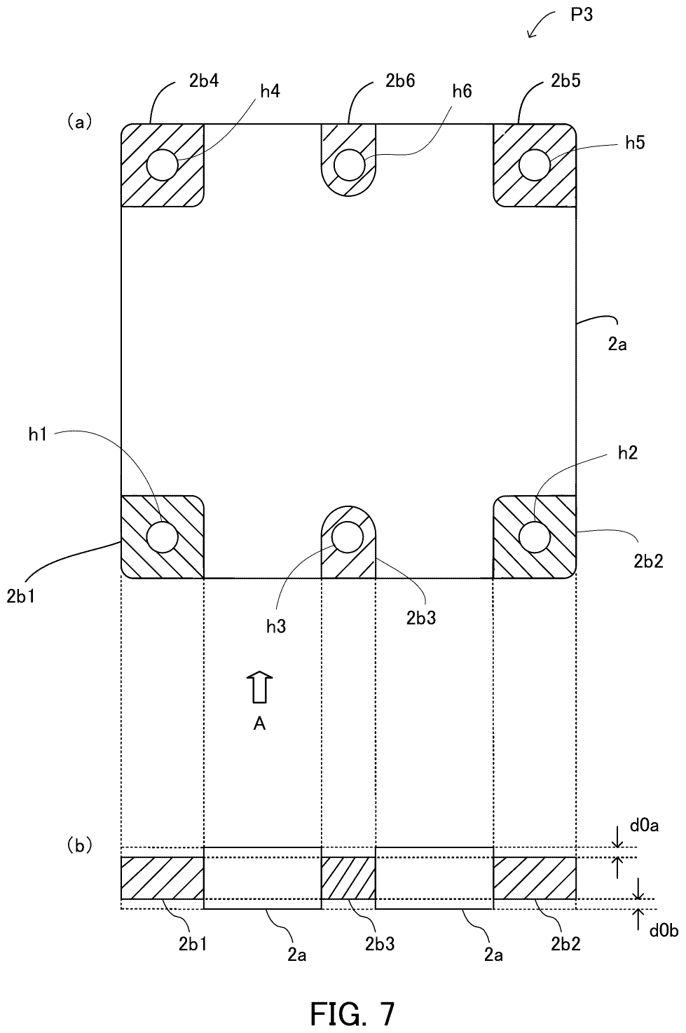

Since, in process P2, the metal-filled bodies 2b1 to 2b6 have not been solidified yet, there are no level differences between surfaces of the silicon carbide formed body 2a and surfaces of the metal-filled bodies 2b1 to 2b6, and the surfaces of the silicon carbide formed body 2a and the surfaces of the metal-filled bodies 2b1 to 2b6 are planarized.

[Process P3] As illustrated in FIG. 7, the metal-filled bodies 2b1 to 2b6 are solidified, and the through-holes h1 to h6 are formed in the metal-filled bodies 2b1 to 2b6, respectively, through cutting processing such as punching.

When the metal-filled bodies 2b1 to 2b6 are solidified, the metal-filled bodies 2b1 to 2b6 become thinner than the silicon carbide formed body 2a due to the difference in linear expansion coefficient between the metal of the silicon carbide formed body 2a and the metal of the metal-filled bodies 2b1 to 2b6. As a result, the level differences d0a and d0b are generated between the silicon carbide formed body 2a and the metal-filled bodies 2b1 to 2b6.

In (b) of FIG. 7, the level differences d0a are generated between the top surface of the silicon carbide formed body 2a and the top surface of the metal-filled bodies 2b1, 2b3, and 2b2, and the level differences d0b are generated between the bottom surface of the silicon carbide formed body 2a and the bottom surface of the metal-filled bodies 2b1, 2b3, and 2b2.

[Process P4] As illustrated in FIG. 8, protective members are formed on surfaces of the metal-filled bodies 2b1 to 2b6 where the level differences d0a and d0b are generated. The protective members are formed to cover at least the peripheries of the through-holes h1 to h6.

In (b) of FIG. 8, the protective member pr1a is formed on a surface of the metal-filled body 2b1, the surface having the level difference d0a with respect to the top surface of the silicon carbide formed body 2a, and the protective member pr1b is formed on a surface of the metal-filled body 2b1, the surface having the level difference d0b with respect to the bottom surface of the silicon carbide formed body 2a. As a result, the top surface of the silicon carbide formed body 2a and the top surface of the protective member pr1a are planarized, and the bottom surface of the silicon carbide formed body 2a and the bottom surface of the protective member pr1b are planarized.

In addition, the protective member pr2a is formed on a surface of the metal-filled body 2b2, the surface having the level difference d0a with respect to the top surface of the silicon carbide formed body 2a, and the protective member pr2b is formed on a surface of the metal-filled body 2b2, the surface having the level difference d0b with respect to the bottom surface of the silicon carbide formed body 2a. As a result, the top surface of the silicon carbide formed body 2a and the top surface of the protective member pr2a are planarized, and the bottom surface of the silicon carbide formed body 2a and the bottom surface of the protective member pr2b are planarized.

Further, a protective member pr3a is formed on a surface of the metal-filled body 2b3, the surface having the level difference d0a with respect to the top surface of the silicon carbide formed body 2a, and a protective member pr3b is formed on a surface of the metal-filled body 2b3, the surface having the level difference d0b with respect to the bottom surface of the silicon carbide formed body 2a. As a result, the top surface of the silicon carbide formed body 2a and the top surface of the protective member pr3a are planarized, and the bottom surface of the silicon carbide formed body 2a and the bottom surface of the protective member pr3b are planarized. The other protective members are also formed in the same manner on surfaces of the metal-filled bodies 2b4 to 2b6, the surfaces having the above-descried level differences.

### <Thickness of Level Difference>

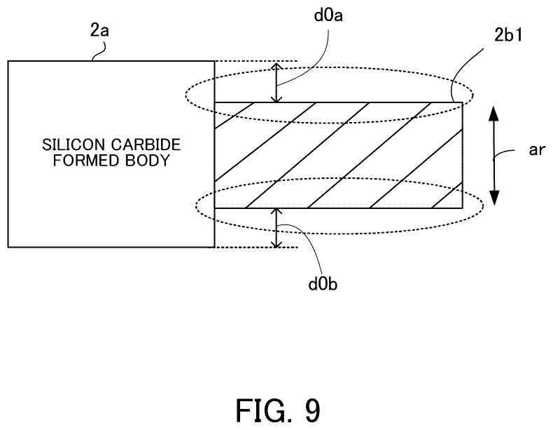

FIG. 9 is a diagram illustrating the thicknesses of the level differences. If the plate thickness of the silicon carbide formed body 2a is 5 mm and if the material of the metal-filled bodies 2b1 to 2b6 is MgSiC, the sum of the level difference d0a and the level difference d0b generated due to the difference in linear expansion coefficient is calculated by “level difference d0a+level difference d0b=68 to 82 (μm)”. That is, the sum of the level differences d0a and d0b accounts for 1.2 to 2% of the thickness of the silicon carbide formed body 2a.

If the plate thickness of the silicon carbide formed body 2a is 5 mm and if the material of the metal-filled bodies 2b1 to 2b6 is AlSiC, the sum of the level differences d0a and d0b is calculated by “level difference d0a+level difference d0b=63 to 77 (μm)”. When the plate thickness of the silicon carbide formed body 2a is doubled, the sum of the level difference d0a and the level difference d0b becomes twice the value described above. That is, the sum of the level differences d0a and d0b accounts for 1.2 to 2% of the thickness of the silicon carbide formed body 2a. The location of the metal-filled body 2b1 is not limited to a center portion on a side wall of the silicon carbide formed body 2a in the plate thickness direction thereof. There are cases in which the metal-filled body 2b1 is formed near the top surface of the silicon carbide formed body 2a or near the bottom surface of the silicon carbide formed body 2a as indicated by an arrow ar, depending on its solidification (the sum of the level differences does not change).

### <Reduction of Generation of Stress>

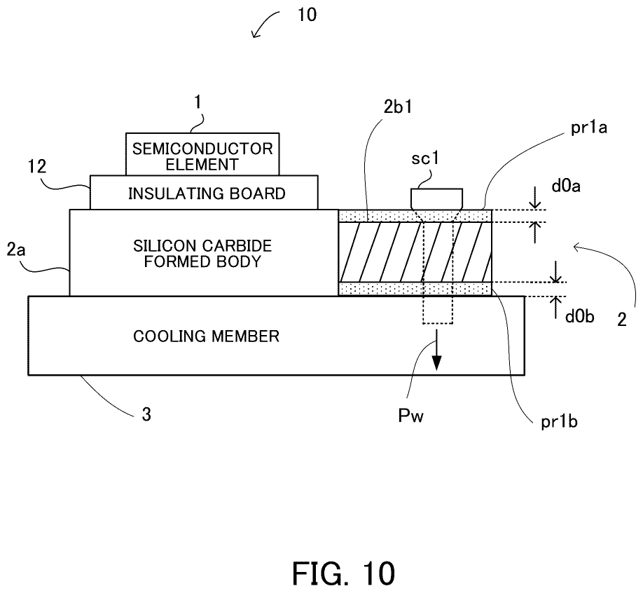

FIG. 10 illustrates reduction of the generation of the stress. The semiconductor device 10 includes the base plate 2, the insulating board 12, the semiconductor element 1, the cooling member 3, and the protective members pr1a and pr1b. The base plate 2 includes the silicon carbide formed body 2a and the metal-filled body 2b1, and the semiconductor element 1 is mounted on the top surface of the silicon carbide formed body 2a via the insulating board 12.

The cooling member 3 is attached to the bottom surface of the base plate 2. The cooling member 3 is fastened to the base plate 2 with the screw sc1 passing through the through-hole in the metal-filled body 2bl.

As described above, in the case of the semiconductor device 10 according to the present embodiment, the protective member pr1a is formed on a surface of the metal-filled body 2b1, the surface having the level difference d0a with respect to the top surface of the silicon carbide formed body 2a, and the protective member pr1b is formed on a surface of the metal-filled body 2b1, the surface having the level difference d0b with respect to the bottom surface of the silicon carbide formed body 2a. The top surface of the silicon carbide formed body 2a and the top surface of the protective member pr2a are planarized, and the bottom surface of the silicon carbide formed body 2a and the bottom surface of the protective member pr2b are planarized. The protective members pr1a and pr1b are formed such that the sum of the thickness of the protective member pr1a and the thickness of the protective member pr1b accounts for 1.2 to 2% of the thickness of the silicon carbide formed body 2a. In this case, because the sum of the level differences d0a and d0b is 1.2 to 2% of the thickness of the silicon carbide formed body 2a, the top surface of the silicon carbide formed body 2a and the top surface of the protective member pr2a are suitably planarized, and the bottom surface of the silicon carbide formed body 2a and the bottom surface of the protective member pr2b are suitably planarized.

Since this construction does not have the level differences d0a and d0b, even when the axial force Pw of the screw sc1 is applied to the base plate 2 and the cooling member 3, the fulcrum of the principle of leverage is not generated. Thus, this construction reduces the generation of the unnecessary stress applied to various members of the semiconductor device 10. Therefore, the metal-filled body 2b1 is not distorted by the axial force Pw generated by fastening of the screw sc1, and the torque loss of the screw sc1 is prevented. Further, the insulating board 12 and the semiconductor element 1 are prevented from being damaged or deteriorated. The protective members pr1a, pr1b, pr2a, and pr2b are formed to cover at least the peripheries of their respective through-holes. In this case, it is possible to reduce the generation of the fulcrum of the principle of leverage and to reduce the generation of the unnecessary stress applied to various members of the semiconductor device 10.

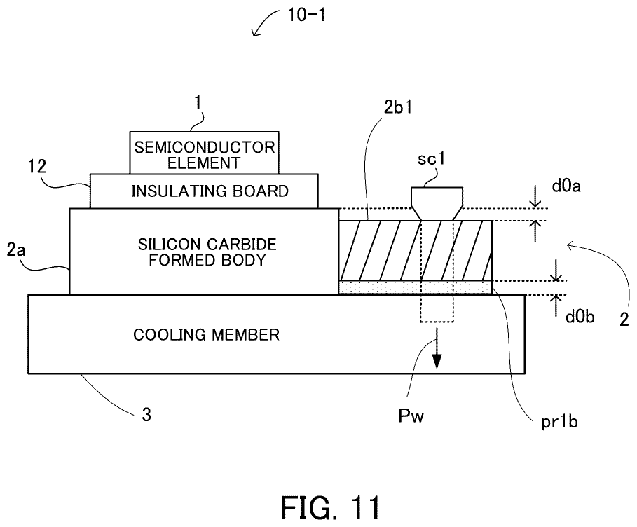

FIG. 11 is a diagram illustrating a modification of the construction of the semiconductor device according to the present embodiment. A semiconductor device 10-1 includes a base plate 2, an insulating board 12, a semiconductor element 1, a cooling member 3, and a protective member pr1b. The construction illustrated in FIG. 11 differs from the construction illustrated in FIG. 10 in that a protective member pr1a is not formed for a level difference d0a generated near the surface on which the insulating board 12 is mounted.

That is, in the semiconductor device 10-1 according to the present embodiment, the protective member pr1b is formed on a surface of a metal-filled body 2b1, the surface having the level difference d0b with respect to the bottom surface of a silicon carbide formed body 2a, such that the bottom surface of the silicon carbide formed body 2a and the bottom surface of the protective member pr1b are planarized. The protective member pr1b has an elastic modulus that planarizes the bottom surface of the silicon carbide formed body 2a and the bottom surface of the protective member pr1b when the base plate 2 and the cooling member 3 are fastened to each other with a screw sc1.

Thus, the construction in which only the protective member pr1b is formed on a surface of the metal-filled body 2b1, the surface being located near the bottom surface of the silicon carbide formed body 2a, also reduces the generation of the unnecessary stress due to an axial force Pw generated by fastening of the screw sc1.

As described above, according to the present embodiment, the base plate includes the silicon carbide formed body and the metal-filled bodies, and the through-holes are formed in the metal-filled bodies. The protective members having a hardness lower than that of the silicon carbide formed body are formed on surfaces of the metal-filled bodies of the base plate.

This construction reduces the generation of the unnecessary stress applied to various members of the device. As a result, the fastening torque of the screws is increased, and the torque loss due to distortion of the metal-filled bodies is prevented. Furthermore, since no unnecessary stress is applied to the product, occurrence of a product failure is reduced.

While an embodiment has thus been described as an example, any one of the individual elements in the embodiment may be replaced by a different element having an equivalent function. In addition, other elements or steps may be added. Two or more elements (features) in the above-described embodiment may be combined with each other.

In one aspect, it is possible to reduce generation of unnecessary stress applied to various members of a device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a base plate that includes
a body plate containing silicon carbide,
a metal-filled body having a top surface and a bottom surface opposite to each other, and having a through hole, and
a protective member disposed on at least the bottom surface of the metal-filled body and having a hardness less than a hardness of the body plate;
an insulating board disposed on the base plate;
a semiconductor element mounted on a top surface of the base plate via the insulating board; and
a cooling member that is attached to a bottom surface of the base plate and is fastened to the base plate with a screw that passes through the through-hole.

2. The semiconductor device according to claim 1, wherein
the metal-filled body is arranged adjacent to the body plate,
the protective member includes a top protective member and a bottom protective member, respectively disposed on the top surface and the bottom surface of the metal-filled body such that a surface of the top protective member is flush with a top surface of the body plate and a bottom surface of the bottom protective member is flush with the bottom surface of the body plate.

3. The semiconductor device according to claim 2, wherein
the bottom protective member has an elastic modulus that is set such that a pressure from the screw that fastens the base plate to the cooling member causes the bottom surface of the body plate to be flush with the bottom surface of the bottom protective member.

4. The semiconductor device according to claim 1, wherein
the metal-filled body is arranged adjacent to the body plate, and
the protective member is disposed on the bottom surface of the metal-filled body such that the bottom surface of the body plate is flush with a bottom surface of the bottom protective member.

5. The semiconductor device according to claim 4, wherein
the protective member has an elastic modulus that is set such that the bottom surface of the body plate is maintained flush with the bottom surface of the bottom protective member by the screw that fastens the base plate to the cooling member.

6. The semiconductor device according to claim 1, wherein the body plate is made of MgSiC or AlSiC.

7. The semiconductor device according to claim 1, wherein the metal-filled body is made of Mg or Al.

8. The semiconductor device according to claim 1, wherein the protective member is a metal plate or is made of an elastic material.

9. The semiconductor device according to claim 8, wherein the metal plate is made of Cu, Al, or Fe.

10. The semiconductor device according to claim 8, further comprising a thermal compound disposed between the base plate and the cooling member, wherein
the protective member is a tape made of the elastic material, and
a thermal conductivity of the tape is equal to or greater than a thermal conductivity of the thermal compound.

11. The semiconductor device according to claim 1, wherein
the protective member includes a top protective member and a bottom protective member, respectively disposed on the top surface and the bottom surface of the metal-filled body, a sum of a thickness of the top protective member and a thickness of the bottom protective member being in a range of 1.2% to 2% of a thickness of the body plate.

12. The semiconductor device according to claim 1, wherein an area of the protective member is equal to an area covering the top surface or the bottom surface of the metal-filled body.

13. The semiconductor device according to claim 1, wherein a thickness of the body plate is greater than a thickness of the metal-filled body.

14. The semiconductor device according to claim 1, wherein the metal-filled body is arranged at an outer periphery of the base plate or at a corner of the base plate.

15. The semiconductor device according to claim 1, wherein the protective member covers at least a periphery of the through-hole of the metal-filled body.

16. A semiconductor device manufacturing method, comprising:
molding a base plate that includes a body plate formed by firing silicon carbide to have a shape in which one or more recesses are formed at an outer periphery thereof, and one or more metal-filled bodies formed by injecting a molten liquid of a metal composite into the one or more recesses of the body plate;
forming one or more through-holes in the base plate by performing cutting processing respectively on the one or more metal-filled bodies;
forming one or more protective members having a hardness less than a hardness of the body plate on surfaces of the one or more metal-filled bodies; and
mounting a semiconductor element on a top surface of the base plate via an insulating board.
